(19) United States
(12) Patent Application Publication
(10) Pub. No.: US 2026/0331866 A1
(43) Pub. Date: Oct. 22, 2026

(54) LIGHT-EMITTING APPARATUS AND MANUFACTURING METHOD THEREOF

(71) Applicant: SONY SEMICONDUCTOR SOLUTIONS CORPORATION, KANAGAWA (JP)

(72) Inventor: SHOGO ONO, KANAGAWA (JP)

(21) Appl. No.: 18/994,785

(22) PCT Filed: Jun. 27, 2023
(86) PCT No.: PCT/JP2023/023708

§ 371 Date: Jan. 15, 2025

(30) Foreign Application Priority Data
Jul. 26, 2022 (JP) 2022-119077

(51) Int. Cl. H01S 5/028; H01S 5/02253; H01S 5/02315; H01S 5/183

(52) U.S. Cl. CPC H01S 5/028; H01S 5/02253; H01S 5/02315; H01S 5/183

(57) ABSTRACT

[Problem] The present disclosure provides a light-emitting apparatus capable of suitably protecting a substrate after singulation and a manufacturing method thereof. [Solution] A light-emitting apparatus according to the present disclosure includes: a substrate; a light-emitting element provided on a first surface of the substrate; a lens provided on a second surface of the substrate; and a film provided on a third surface between the first surface and the second surface of the substrate.

### TECHNICAL FIELD

The present disclosure relates to a light-emitting apparatus and to a manufacturing method thereof.

### BACKGROUND ART

Surface-emitting lasers such as a VCSEL (Vertical Cavity Surface Emitting Laser) are known as a type of a semiconductor laser. Generally, in a light-emitting apparatus using a surface-emitting laser, a plurality of light-emitting elements are provided in a two-dimensional array pattern on a front surface or a rear surface of a substrate.

### CITATION LIST

### Patent Literature

### PTL 1

Japanese Translation of PCT Application No. 2004-526194

### SUMMARY

### Technical Problem

When the substrate described above is singulated, adherence of deposits on side surfaces of the singulated substrate and oxide generation on the side surfaces of the singulated substrate become a problem. The deposits are created due to, for example, dry etching when singulating the substrate. On the other hand, the oxides are created due to, for example, oxidation of the side surfaces of the substrate. The deposits and oxides cause dust if they fall off the side surfaces of the substrate.

In consideration thereof, the present disclosure provides a light-emitting apparatus capable of suitably protecting a substrate after singulation and a manufacturing method thereof.

### Solution to Problem

A light-emitting apparatus according to a first aspect of the present disclosure includes: a substrate; a light-emitting element provided on a first surface of the substrate; a lens provided on a second surface of the substrate; and a film provided on a third surface between the first surface and the second surface of the substrate. Accordingly, for example, by forming the film on the third surface of the substrate, the substrate after singulation can be suitably protected.

In addition, in the first aspect, the film may be provided on the second surface and the third surface of the substrate. Accordingly, for example, by forming the film so as to straddle the second surface and the third surface of the substrate, the substrate after singulation can be suitably protected.

Furthermore, in the first aspect, the film may cover the lens. Accordingly, for example, the substrate after singulation can be suitably protected by the film for the lens.

In addition, in the first aspect, the film need not come into contact with the light-emitting element. Accordingly, for example, the substrate after singulation can be suitably protected by the film which is not used for the light-emitting element.

Furthermore, in the first aspect, the film may be an anti-reflective film.

Accordingly, for example, the substrate after singulation can be suitably protected by the anti-reflective film.

Furthermore, in the first aspect, the film may contain silicon. Accordingly, for example, the substrate after singulation can be suitably protected by the silicon-based film that can be formed in an inexpensive manner.

In addition, in the first aspect, the film may include a first film provided on the third surface of the substrate and a second film provided via the first film on the third surface of the substrate. Accordingly, for example, the substrate after singulation can be suitably protected by the film which can be used as an anti-reflective film or the like.

Furthermore, in the first aspect, the first film may contain silicon and nitrogen and the second film may contain silicon and oxygen. Accordingly, for example, the substrate after singulation can be suitably protected by the film which can be used as an anti-reflective film or the like.

In addition, in the first aspect, the substrate may be a compound semiconductor substrate. Accordingly, for example, even when using a compound semiconductor substrate of which brittleness or susceptibility to oxidation is a problem, the substrate after singulation can be suitably protected.

Furthermore, in the first aspect, the substrate may contain gallium and arsenide.

Accordingly, for example, even when using a compound semiconductor substrate such as a GaAs (gallium arsenide) substrate, the substrate after singulation can be suitably protected.

In addition, in the first aspect, the third surface of the substrate may have a tapered shape. Accordingly, for example, even when singulation of the substrate is performed by dry etching or the like, the substrate after singulation can be suitably protected.

A manufacturing method of a light-emitting apparatus according to a second aspect of the present disclosure includes the steps of: forming a light-emitting element on a first surface of a substrate; forming a lens on a second surface of the substrate; singulating the substrate; and forming a film on a third surface between the first surface and the second surface of the substrate after singulation of the substrate. Accordingly, for example, by forming the film on the third surface of the substrate, the substrate after singulation can be suitably protected.

In addition, in the second aspect, the film may be formed on the second surface and the third surface of the substrate after singulation of the substrate. Accordingly, for example, by forming the film so as to straddle the second surface and the third surface of the substrate, the substrate after singulation can be suitably protected.

Furthermore, in the second aspect, the film may be formed so as to cover the lens. Accordingly, for example, the substrate after singulation can be suitably protected by the film for the lens.

In addition, in the second aspect, the film may be formed so as not to come into contact with the light-emitting element. Accordingly, for example, the substrate after singulation can be suitably protected by the film which is not used for the light-emitting element.

Furthermore, in the second aspect, the film may be an anti-reflective film. Accordingly, for example, the substrate after singulation can be suitably protected by the anti-reflective film.

In addition, in the second aspect, the film may be formed so as to include a first film formed on the third surface of the substrate and a second film formed via the first film on the third surface of the substrate. Accordingly, for example, the substrate after singulation can be suitably protected by the film which can be used as an anti-reflective film or the like.

Furthermore, in the second aspect, the substrate may be a compound semiconductor substrate. Accordingly, for example, even when using a compound semiconductor substrate of which brittleness or susceptibility to oxidation is a problem, the substrate after singulation can be suitably protected.

In addition, in the second aspect, the third surface of the substrate may be formed by singulation of the substrate. Accordingly, for example, by protecting the third surface created by singulation by the film, the substrate after singulation can be suitably protected.

Furthermore, in the second aspect, the singulation of the substrate may be performed by dry etching. Accordingly, for example, even when deposits are created by dry etching, the substrate after singulation can be suitably protected.

### BRIEF DESCRIPTION OF DRAWINGS

FIG. 1 is a block diagram showing a configuration example of a ranging apparatus according to a first embodiment.

FIG. 2 is a diagram for describing an STL (Structured Light) method according to the first embodiment.

FIG. 3 is a sectional view showing an example of a structure of a light-emitting apparatus according to the first embodiment.

FIG. 4 is a sectional view showing the structure of the light-emitting apparatus shown in B in FIG. 3.

FIG. 5 is a sectional view and a plan view showing a structure of the light-emitting apparatus according to the first embodiment.

FIG. 6 is a plan view and a sectional view showing a structure of a substrate of the light-emitting apparatus according to the first embodiment.

FIG. 7 is a sectional view (1/3) showing a manufacturing method of a light-emitting apparatus according to a comparative example.

FIG. 8 is a sectional view (2/3) showing the manufacturing method of a light-emitting apparatus according to the comparative example.

FIG. 9 is a sectional view (3/3) showing the manufacturing method of a light-emitting apparatus according to the comparative example.

FIG. 10 is a sectional view (1/3) showing a manufacturing method of the light-emitting apparatus according to the first embodiment.

FIG. 11 is a sectional view (2/3) showing the manufacturing method of the light-emitting apparatus according to the first embodiment.

FIG. 12 is a sectional view (3/3) showing the manufacturing method of the light-emitting apparatus according to the first embodiment.

FIG. 13 is a sectional view for comparing the first embodiment and the comparative example with each other.

FIG. 14 is a sectional view (1/2) showing a manufacturing method of the light-emitting apparatus according to the first embodiment.

FIG. 15 is a sectional view (2/2) showing the manufacturing method of the light-emitting apparatus according to the first embodiment.

FIG. 16 is a sectional view showing details of the manufacturing method of the light-emitting apparatus according to the first embodiment.

FIG. 17 is a sectional view showing a structure of the light-emitting apparatus according to the first embodiment and a structure of a light-emitting apparatus according to a modification of the first embodiment.

FIG. 18 is a sectional view showing a structure of a light-emitting apparatus according to another modification of the first embodiment.

FIG. 19 is a sectional view showing an example of a structure of a substrate of a light-emitting apparatus according to a second embodiment.

FIG. 20 is a sectional view showing an example of a structure of a substrate of a light-emitting apparatus according to a third embodiment.

### DESCRIPTION OF EMBODIMENTS

Hereinafter, embodiments of the present disclosure will be described with reference to drawings.

### First Embodiment

### (1) Ranging Apparatus 1 According to First Embodiment

### (1.1) Configuration of Ranging Apparatus 1

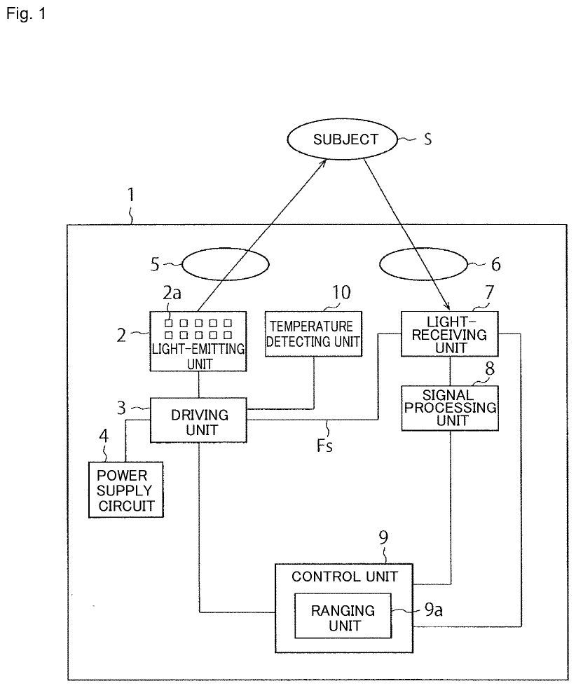

FIG. 1 is a block diagram showing a configuration example of a ranging apparatus 1 according to a first embodiment.

As illustrated, the ranging apparatus 1 includes a light-emitting unit 2, a driving unit 3, a power supply circuit 4, a light-emitting side optical system 5, a light-receiving side optical system 6, a light-receiving unit 7, a signal processing unit 8, a control unit 9, and a temperature detecting unit 10.

The light-emitting unit 2 emits light using a plurality of light sources. The light-emitting unit 2 according to the present example includes a light-emitting element 2a using a VCSEL (Vertical Cavity Surface Emitting LASER) as each light source and the light-emitting unit 2 is constructed by arraying the light-emitting elements 2a in a predetermined mode such as a matrix pattern.

The driving unit 3 is constituted of a power supply circuit for driving the light-emitting unit 2.

The power supply circuit 4 generates power supply voltage of the driving unit 3 based on input voltage from, for example, a battery or the like (not illustrated) provided in the ranging apparatus 1. The driving unit 3 drives the light-emitting unit 2 based on the power supply voltage.

A subject S as a ranging object is irradiated with light emitted from the light-emitting unit 2 via the light-emitting side optical system 5. In addition, reflected light from the subject S of the light irradiated in this manner is incident to a light-receiving surface of the light-receiving unit 7 via the light-receiving side optical system 6.

The light-receiving unit 7 is, for example, a light-receiving element such as a CCD (Charge Coupled Device) sensor or a CMOS (Complementary Metal Oxide Semiconductor) sensor and receives reflected light from the subject S which is incident via the light-receiving side optical system 6 as described above, converts the reflected light into an electric signal, and outputs the electric signal.

The light receiving unit 7 executes, with respect to an electric signal obtained by photoelectrically converting received light, for example, CDS (Correlated Double Sampling) processing, AGC (Automatic Gain Control) processing, and A/D (Analog/Digital) conversion processing. In addition, the light-receiving unit 7 outputs a signal as digital data to the signal processing unit 8 in a latter stage.

In addition, the light-receiving unit 7 according to the present example outputs a frame synchronization signal Fs to the driving unit 3. Accordingly, the driving unit 3 can cause the light-emitting elements 2a in the light-emitting unit 2 to emit light at timings in accordance with a frame period of the light-receiving unit 7.

For example, the signal processing unit 8 is configured as a signal processing processor such as a DSP (Digital Signal Processor). The signal processing unit 8 subjects a digital signal input from the light-receiving unit 7 to various kinds of signal processing.

The control unit 9 is constituted of, for example, a microcomputer including a CPU (Central Processing Unit), a ROM (Read Only Memory), and a RAM (Random Access Memory) or an information processing apparatus such as a DSP and performs control of the driving unit 3 for controlling a light-emitting operation by the light-emitting unit 2 and control related to a light-receiving operation by the light-receiving unit 7.

The control unit 9 includes a function as a ranging unit 9a. The ranging unit 9a measures a distance to the subject S based on a signal input via the signal processing unit 8 (in other words, a signal obtained by receiving reflected light from the subject S). The ranging unit 9a according to the present example performs distance measurement with respect to each portion of the subject S in order to enable a three-dimensional shape of the subject S to be specified.

A specific ranging method in the ranging apparatus 1 will be reiterated later.

The temperature detecting unit 10 detects a temperature of the light-emitting unit 2. As the temperature detecting unit 10, for example, a configuration of performing temperature detection using a diode can be adopted.

In the present example, information of the temperature detected by the temperature detecting unit 10 is supplied to the driving unit 3 and the driving unit 3 is capable of driving the light-emitting unit 2 based on the temperature information.

### (1.2) Ranging Method

As a ranging method in the ranging apparatus 1, for example, a ranging method based on an STL (Structured Light) method or a ToF (Time of Flight) method can be adopted.

The STL method is a method of measuring a distance based on an image of the subject S irradiated with light having a predetermined light/dark pattern such as a dot pattern or a lattice pattern.

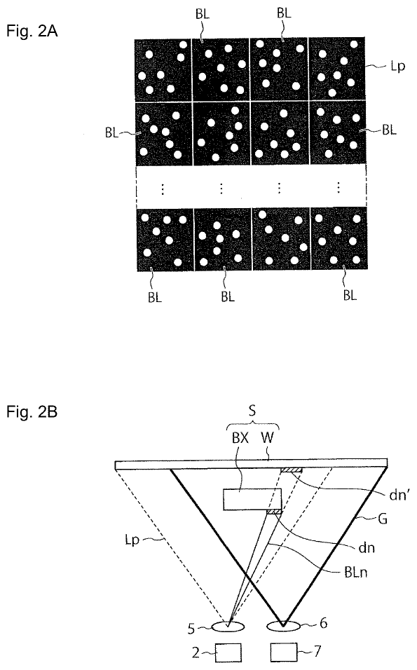

FIG. 2 is a diagram for describing the STL method according to the first embodiment.

In the STL method, for example, the subject S is irradiated with pattern light Lp with a dot pattern such as that shown in A in FIG. 2. The pattern light Lp is divided into a plurality of blocks BL and each block BL is assigned a different dot pattern (so as to prevent dot patterns from being duplicated between blocks B).

B in FIG. 2 is an explanatory diagram of a principle of ranging by the STL method.

In this example, a wall W and a box BX arranged in front of the wall W are considered the subject S and the subject S is irradiated with the pattern light Lp.

In the diagram, “G” schematically represents an angle of view of the light-receiving unit 7.

In addition, in the diagram, “BLn” signifies light of a given block BL in the pattern light Lp and “dn” signifies a dot pattern of a block BLn projected on a received-light image of the light-receiving unit 7.

When the box BX in front of the wall W does not exist, the dot pattern of the block BLn is projected on the received-light image at a position denoted as “dn” in the drawing. In other words, positions at which the pattern of the block BLn is projected in the received-light image differ between when the box BX exists and when the box BX does not exist and, specifically, a distortion of the pattern occurs.

The STL method is a method of obtaining a shape or a depth of the subject S by utilizing the fact that a pattern irradiated in this manner is distorted by a physical shape of the subject S. Specifically, the method involves obtaining a shape or a depth of the subject S from the manner in which the pattern is distorted.

When adopting the STL method, for example, an IR (Infrared) light-receiving unit adopting a global shutter system is used as the light-receiving unit 7. In addition, in the case of the STL method, the ranging unit 9a controls the driving unit 3 so that the light-emitting unit 2 emits pattern light, detects a distortion in a pattern with respect to an image signal obtained via the signal processing unit 8, and calculates a distance based on how the pattern is distorted.

Next, the ToF method is a method of measuring a distance to an object by detecting a time of flight (time difference) of light emitted from the light-emitting unit 2 until the light is reflected by the object and reaches the light-receiving unit 7.

When a so-called direct ToF (dToF) method is adopted as the ToF method, an SPAD (Single Photon Avalanche Diode) is used as the light-receiving unit 7 and the light-emitting unit 2 is pulse-driven. In this case, based on a signal input via the signal processing unit 8, the ranging unit 9a calculates a time difference from light emission to light reception of light emitted from the light-emitting unit 2 and received by the light-receiving unit 7 and calculates a distance of each part of the subject S based on the time difference and the speed of light.

When a so-called indirect ToF (iToF) method (phase difference method) is adopted as the ToF method, for example, a light-receiving unit capable of receiving IR is used as the light-receiving unit 7.

### (2) Light-Emitting Apparatus 1a According to First Embodiment

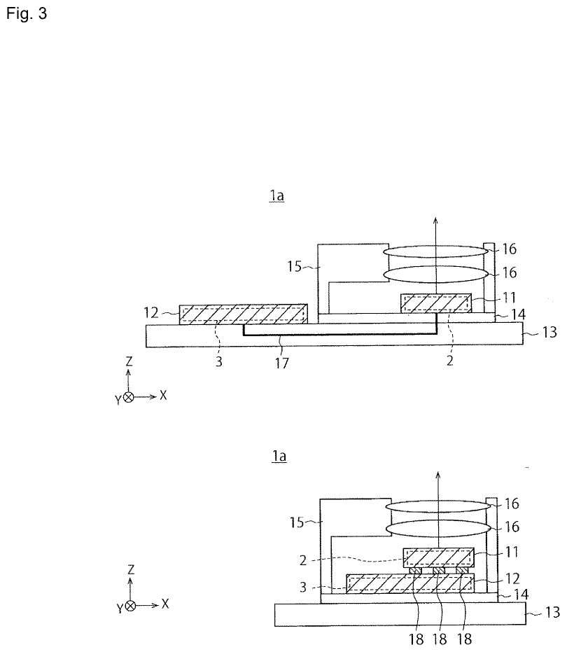

FIG. 3 is a sectional view showing an example of a structure of a light-emitting apparatus 1a according to the first embodiment. The light-emitting apparatus 1a according to the present embodiment may be a part of the ranging apparatus 1 or may be the ranging apparatus 1 itself.

A in FIG. 3 shows a first example of the structure of the light-emitting apparatus 1a according to the present embodiment. The light-emitting apparatus 1a according to the example includes an LD (Laser Diode) chip 11 including the light-emitting unit 2 described above, an LDD (Laser Diode Driver) substrate 12 including the driving unit 3 described above, a mounting substrate 13, a heat dissipation substrate 14, a correcting lens holding unit 15, one or more correcting lenses 16, and wiring 17. The LD chip 11 is also referred to as a VCSEL substrate.

A in FIG. 3 shows an X axis, a Y axis, and a Z axis which are perpendicular to each other. An X direction and a Y direction correspond to a lateral direction (horizontal direction) and a Z direction corresponds to a longitudinal direction (a perpendicular direction). In addition, a +Z direction corresponds to an upward direction and a −Z direction corresponds to a downward direction. The −Z direction may strictly coincide with the direction of gravitational force or may not strictly coincide with the direction of gravitational force.

The LD chip 11 is arranged on the mounting substrate 13 via the heat dissipation substrate 14 and the LDD substrate 12 is also arranged on the mounting substrate 13. The mounting substrate 13 is, for example, a printed circuit board. The light-receiving unit 7 and the signal processing unit 8 described above may be further arranged on the mounting substrate 13. The heat dissipation substrate 14 is, for example, a ceramic substrate such as an Al₂O₃ (aluminum oxide) substrate or an AlN (aluminum nitride) substrate.

The correcting lens holding unit 15 is arranged on the heat dissipation substrate 14 so as to surround the LD chip 11 and holds one or more correcting lenses 16 above the LD chip 11. The correcting lenses 16 are included in the light-emitting side optical system 5 described above. Light emitted from the light-emitting unit 2 inside the LD chip 11 is corrected by the correcting lenses 16 and, subsequently, the subject S described earlier is irradiated with the corrected light. As an example, A in FIG. 3 shows two correcting lenses 16 being held by the correcting lens holding unit 15.

The wiring 17 is provided on a front surface and a rear surface of the mounting substrate 13, provided inside the mounting substrate 13, and the like and electrically connects the LD chip 11 and the LDD substrate 12 to each other. The wiring 17 is, for example, printed wiring which is provided on the front surface and the rear surface of the mounting substrate 13 or via wiring which penetrates the mounting substrate 13. The wiring 17 according to the present embodiment further passes inside or near the heat dissipation substrate 14.

B in FIG. 3 shows a second example of the structure of the light-emitting apparatus 1a according to the present embodiment. While the light-emitting apparatus 1a according to the present example includes the same components as the light-emitting apparatus 1a according to the first example, the light-emitting apparatus 1a according to the present example includes a bump 18 instead of the wiring 17.

In B in FIG. 3, the LDD substrate 12 is arranged on the heat dissipation substrate 14 and the LD chip 11 is arranged on the LDD substrate 12. By arranging the LD chip 11 on the LDD substrate 12 in this manner, the mounting substrate 13 can be downsized as compared to the first example. In B in FIG. 3, the LD chip 11 is arranged on the LDD substrate 12 via the bump 18 and the LD chip 11 is electrically connected to the LDD substrate 12 by the bump 18. For example, the bump 18 is formed of a metal such as gold (Au).

Hereinafter, the light-emitting apparatus 1a according to the present embodiment will be described on the assumption that the light-emitting apparatus 1a has the structure according to the second example shown in B in FIG. 3. However, with the exception of a description of structures specific to the second example, the following description is also applicable to the light-emitting apparatus 1a having the structure according to the first example.

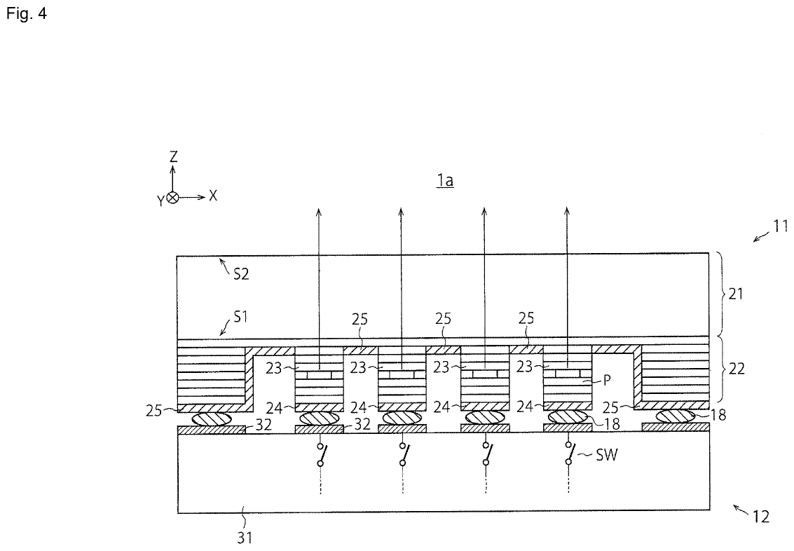

FIG. 4 is a sectional view showing the structure of the light-emitting apparatus 1a shown in B in FIG. 3.

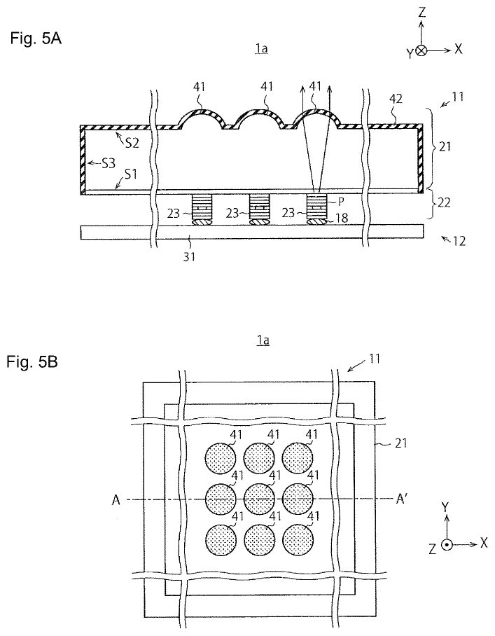

FIG. 4 shows cross sections of the LD chip 11 and the LDD substrate 12 inside the light-emitting apparatus 1a. As shown in FIG. 4, the LD chip 11 includes a substrate 21, a laminated film 22, a plurality of light-emitting elements 23, a plurality of anode electrodes 24, and a cathode electrode 25, and the LDD substrate 12 includes a substrate 31 and a plurality of connection pads 32. The light-emitting elements 23 shown in FIG. 4 differ from the specific example of the light-emitting element 2a described above. In FIG. 4, illustration of a lens 41 and an anti-reflective film 42 to be described later has been omitted (refer to FIG. 5).

For example, the substrate 21 is a compound semiconductor substrate such as a GaAs (gallium arsenide) substrate. FIG. 4 shows a front surface S1 of the substrate 21 facing the −Z direction and a rear surface S2 of the substrate 21 facing the +Z direction. The front surface S1 and the rear surface S2 shown in FIG. 4 are perpendicular to the Z direction. In FIG. 4, the front surface S1 is a lower surface of the substrate 21 and the rear surface S2 is an upper surface of the substrate 21. The front surface S1 and the rear surface S2 of the substrate 21 are, respectively, examples of the first surface and the second surface of the substrate according to the present disclosure.

The laminated film 22 includes a plurality of layers laminated on the front surface S1 of the substrate 21. Examples of the layers include an n-type semiconductor layer, an active layer, a p-type semiconductor layer, a light reflection layer, and an insulating layer having a light emission window. The laminated film 22 includes a plurality of post portions P which protrude in the −Z direction. A part of the post portions P constitutes the plurality of light-emitting elements 23.

The light-emitting elements 23 are provided on the front surface S1 of the substrate 21 as a part of the laminated film 22. The light-emitting elements 23 according to the present embodiment have a VCSEL structure and emit light in the +Z direction. As shown in FIG. 4, light emitted from each light-emitting element 23 is transmitted inside the substrate 21 from the front surface S1 to the rear surface S2 of the substrate 21 and enters the correcting lens 16 described above from the substrate 21. In this manner, the LD chip 11 according to the present embodiment is configured as a backside emission-type VCSEL chip. The light-emitting elements 23 are also referred to as mesa portions.

Each anode electrode 24 is formed on a lower surface of a corresponding light-emitting element 23. The cathode electrode 25 is continuously formed on a lower surface and a side surface of the post portion P other than the light-emitting element 23 and a lower surface of the laminated film 22 between the post portions P. Therefore, the LD chip 11 according to the present embodiment includes a plurality of the anode electrodes 24 and one cathode electrode 25. Each light-emitting element 23 emits light when a current flows between a corresponding anode electrode 24 and the cathode electrode 25.

As described above, the LD chip 11 is arranged on the LDD substrate 12 via the bump 18 and the LD chip 11 is electrically connected to the LDD substrate 12 by the bump 18. Specifically, the connection pad 32 is formed on the substrate 31 included in the LDD substrate 12 and the post portion P is arranged on the connection pad 32 via the bump 18. Each post portion P is arranged on the bump 18 via the anode electrode 24 or the cathode electrode 25. For example, the substrate 31 is a semiconductor substrate such as a Si (silicon) substrate. For example, the connection pad 32 is formed of a metal such as copper (Cu).

As described above, the LDD substrate 12 includes the driving unit 3 which drives the light-emitting unit 2 in the LD chip 11. FIG. 4 schematically shows a plurality of switches SW in in the driving unit 3. Each switch SW is electrically connected to a corresponding light-emitting element 23 via the bump 18. The driving unit 3 according to the present embodiment is capable of controlling (on/off) the switches SW on an individual basis. Therefore, the driving unit 3 can drive the plurality of light-emitting elements 23 on the basis of each light-emitting element 23.

Accordingly, light emitted from the light-emitting unit 2 can be controlled precisely such as causing only the light-emitting elements 23 necessary for ranging to emit light. Such individual control of the light-emitting elements 23 is realized by arranging the LDD substrate 12 below the LD chip 11 to make it easier for each light-emitting element 23 to be electrically connected to the switch SW corresponding to the light-emitting element 23.

FIG. 5 is a sectional view and a plan view showing a structure of the light-emitting apparatus 1a according to the first embodiment.

A in FIG. 5 shows cross sections of the LD chip 11 and the LDD substrate 12 inside the light-emitting apparatus 1a in a similar manner to FIG. 4. As shown in A in FIG. 5, the LD chip 11 includes the substrate 21, the laminated film 22, a plurality of the light-emitting elements 23, a plurality of the anode electrodes 24, and the cathode electrode 25, and the LDD substrate 12 includes the substrate 31 and a plurality of the connection pads 32. It should be noted that illustration of the anode electrodes 24, the cathode electrode 25, and the connection pads 32 has been omitted in A in FIG. 5.

In A in FIG. 5, the substrate 21 has a front surface S1 facing the −Z direction, a rear surface S2 facing the +Z direction, and a plurality of side surfaces S3 between the front surface S1 and the rear surface S2. While the side surfaces S3 are parallel to the Z direction in A in FIG. 5, alternatively, the side surfaces S3 may be inclined with respect to the Z direction. In other words, the side surfaces S3 may have a tapered shape. The shape of the substrate 21 according to the present embodiment is a hexahedron that is nearly a rectangular parallelepiped and has four side surfaces S3. The front surface S1, the rear surface S2, and the side surfaces S3 of the substrate 21 are, respectively, examples of the first surface, the second surface, and the third surface of the substrate according to the present disclosure.

The LD chip 11 according to the present embodiment includes the plurality of light-emitting elements 23 on the front surface S1 of the substrate 21 and, at the same time, includes a plurality of the lenses 41 and the anti-reflective film (AR film) 42 on the rear surface S2 of the substrate 21. The anti-reflective film 42 according to the present embodiment is also formed on the side surfaces S3 of the substrate 21 and is continuously provided on the rear surface S2 and the side surfaces S3 of the substrate 21. The anti-reflective film 42 is an example of the film according to the present disclosure.

The lenses 41 are arranged in a two-dimensional array pattern in a similar manner to the light-emitting elements 23. The lenses 41 according to the present embodiment correspond one-to-one to the light-emitting elements 23, and each lens 41 is arranged in the +Z direction of one light-emitting element 23. In addition, as shown in A in FIG. 5, the lenses 41 according to the present embodiment are provided on the rear surface S2 of the substrate 21 as a part of the substrate 21. Specifically, the lenses 41 according to the present embodiment are convex lenses and are formed as a part of the substrate 21 by machining the rear surface S2 of the substrate 21 into a convex shape. According to the present embodiment, by forming the lenses 41 by etching of the substrate 21, the lenses 41 can be readily formed. Examples of the lenses 41 other than convex lenses will be described later.

The anti-reflective film 42 is formed on the rear surface S2 of the substrate 21 so as to cover the lenses 41. The anti-reflective film 42 according to the present embodiment is formed on the side surfaces S3 of the substrate 21 but not on the front surface S1 of the substrate 21. Therefore, the anti-reflective film 42 according to the present embodiment is not in contact with the light-emitting elements 23. For example, the anti-reflective film 42 has a function of preventing light incident to the lenses 41 from inside the substrate 21 from being reflected to the inside of the substrate 21. For example, the anti-reflective film 42 is a film containing elementary Si (silicon). The anti-reflective film 42 may be formed by only one film or two or more films. The anti-reflective film 42 according to the present embodiment is a laminated film including an SiN film (silicon nitride film) and an SiO₂ film (silicon oxide film) having been laminated in order on the rear surface S2 and the side surfaces S3 of the substrate 21. While the anti-reflective film 42 has a uniform thickness in the present embodiment, alternatively, the thickness of the anti-reflective film 42 may be non-uniform.

Light emitted from the plurality of light-emitting elements 23 described above is transmitted inside the substrate 21 from the front surface S1 to the rear surface S2 of the substrate 21 and enters the plurality of lenses 41 described above. In the present embodiment, light emitted from each light-emitting element 23 is incident to one corresponding lens 41. Accordingly, light emitted from the plurality of light-emitting elements 23 described above can be shaped for each individual lens 41. The light having passed through the plurality of lenses 41 described above passes through the correcting lens 16 (FIG. 3) and the subject S (FIG. 1) is irradiated with the light. An example of a case where the light-emitting elements 23 and the lenses 41 do not correspond one-to-one with each other will be described later.

The side surfaces S3 of the substrate 21 according to the present embodiment are formed by singulation of the substrate 21. For example, when the substrate 21 is singulated by dry etching such as RIE (Reactive Ion Etching), side surfaces S3 with a tapered shape are generally formed. When the substrate 21 is singulated, there is a risk of deposits adhering to the side surfaces S3 of the substrate 21 or oxides being generated on the side surfaces S3 of the substrate 21. There is a risk that such deposits and oxides may cause dust if they fall off the side surfaces S3 of the substrate 21. Therefore, the anti-reflective film 42 according to the present embodiment is formed so as to cover the rear surface S2 and the side surfaces S3 of the substrate 21 after the singulation of the substrate 21. Accordingly, shedding of deposits can be suppressed by covering the deposits with the anti-reflective film 42 and generation of oxide can be suppressed by covering the side surfaces S3 with the anti-reflective film 42 prior to oxidation. Further details of such effects will be provided later.

B in FIG. 5 shows a layout of the lenses 41 on the rear surface S2 of the substrate 21. Ain FIG. 5 shows a cross section taken along line A-A′ shown in B in FIG. 5. In B in FIG. 5, the lenses 41 are arranged in a two-dimensional array pattern or, more specifically, in a square lattice shape on the rear surface S2 of the substrate 21. Note that the lenses 41 may be arranged in a mode other than an arrangement with a square lattice shape or arranged in a mode other than an arrangement with a two-dimensional array pattern.

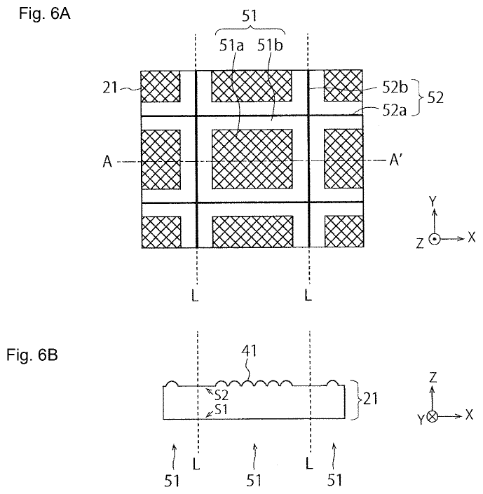

FIG. 6 is a plan view and a sectional view showing a structure of the substrate 21 of the light-emitting apparatus 1a according to the first embodiment. A in FIG. 6 is a plan view showing the structure of the substrate 21 before being diced (singulated) and B in FIG. 6 is a sectional view taken along line A-A′ shown in A in FIG. 6.

As shown in A and B in FIG. 6, the substrate 21 according to the present embodiment includes a plurality of chip regions 51 and a scribe region (dicing region) 52. Each chip region 51 is a region to become one LD chip 11 after dicing of the substrate 21. The scribe region 52 is a region to be cut during dicing of the substrate 21. The substrate 21 according to the present embodiment is divided into a plurality of the chip regions 51 by being cut in the scribe region 52. As a result, the side surfaces S3 of the substrate 21 are formed in each LD chip 11.

Each chip region 51 has a rectangular (or square) planar shape and includes a lens region 51a and a peripheral region 51b. The lens region 51a includes a plurality of the lenses 41 which are arranged in a two-dimensional array pattern (B in FIG. 6). The peripheral region 51b annularly encircles the lens region 51a.

The scribe region 52 has a planar shape that annularly encloses the plurality of chip regions 51 described above for each chip region 51 and includes a plurality of scribe lines (dicing lines) 52a that extend in the X direction and a plurality of scribe lines 52b that extend in the Y direction. The substrate 21 according to the present embodiment is divided into a plurality of the chip regions 51 by cutting the scribe lines 52a and 52b by dry etching (or a dicer). Subsequently, the anti-reflective film 42 (refer to FIG. 5) is formed on the rear surface S2 and the side surface S3 of the substrate 21. Reference sign L denotes a plane that passes through the scribe lines 52b.

### (3) Comparison Between First Embodiment and Comparative Example

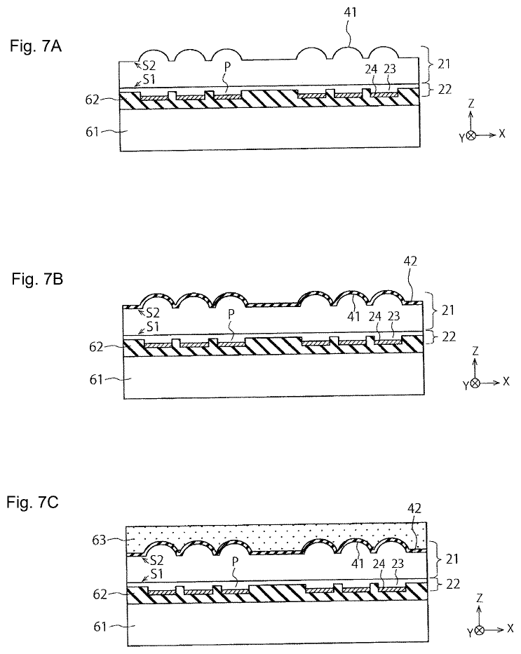

Next, the light-emitting apparatus 1a according to the first embodiment and the light-emitting apparatus 1a according to the comparative example will be compared with each other with reference to FIGS. 7 to 13. The description of the light-emitting apparatus 1a according to the comparative example will use the same reference signs that were used in the description of the light-emitting apparatus 1a according to the present embodiment.

FIGS. 7 to 9 are sectional views showing a manufacturing method of the light-emitting apparatus 1a according to the comparative example.

First, the substrate 21 for the LD chip 11 is prepared, the laminated film 22, a plurality of the light-emitting elements 23, a plurality of the anode electrodes 24, and the cathode electrode 25 (not illustrated) are formed on the front surface S1 of the substrate 21, and a plurality of the lenses 41 are formed on the rear surface S2 of the substrate 21 (A in FIG. 7). In this step, a plurality of the post portions P including the light-emitting elements 23 are formed on the front surface S1 of the substrate 21. Next, the substrate 21 is placed on a supporting substrate 61 via an adhesive layer 62 (A in FIG. 7). As a result, the substrate 21 is bonded to the supporting substrate 61 by the adhesive layer 62. In A in FIG. 7, the front surface S1 of the substrate 21 faces the side of the supporting substrate 61 and the rear surface S2 of the substrate 21 faces an opposite side to the supporting substrate 61.

Next, the anti-reflective film 42 is formed on the rear surface S2 of the substrate 21 (B in FIG. 7). As a result, the lenses 41 are covered by the anti-reflective film 42. In B in FIG. 7, since the light-emitting elements 23 are covered by the adhesive layer 62, the anti-reflective film 42 is not in contact with the light-emitting elements 23.

Next, a resist film 63 is formed on the rear surface S2 of the substrate 21 via the anti-reflective film 42 (C in FIG. 7). The resist film 63 is formed by applying a photoresist material to the anti-reflective film 42.

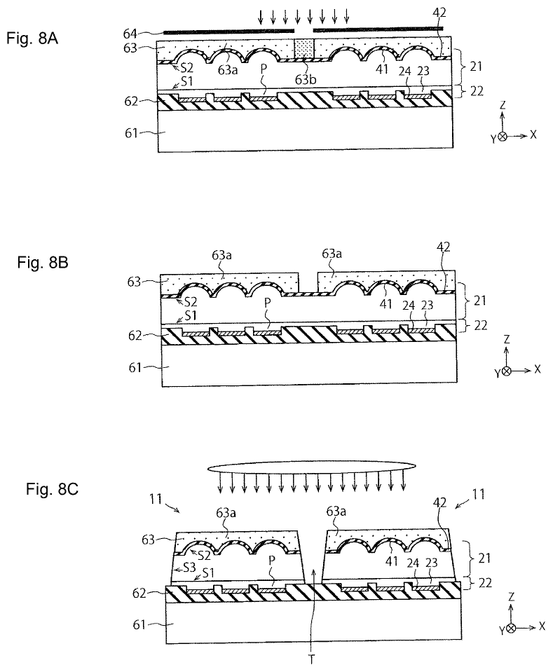

Next, the resist film 63 is exposed using a photomask 64 (A in FIG. 8). As a result, a plurality of non-exposure regions 63a and an exposure region 63b are formed inside the resist film 63. The non-exposure regions 63a are formed so as to form the chip regions 51 and the exposure region 63b is formed so as to form the scribe region 52.

Next, the resist film 63 is developed (B in FIG. 8). As a result, the exposure region 63b is removed and the non-exposure regions 63a remain. In other words, the resist film 63 is patterned in a shape of the non-exposure regions 63a.

Next, the anti-reflective film 42, the substrate 21, and the laminated film 22 are machined by dry etching such as RIE using the resist film 63 (C in FIG. 8). As a result, a trench T is formed so as to penetrate the anti-reflective film 42, the substrate 21, and the laminated film 22 and a plurality of the LD chips 11 is formed from the substrate 21. Furthermore, the side surfaces S3 of the substrate 21 are formed in each LD chip 11. In C in FIG. 8, the side surfaces S3 have a tapered shape due to dry etching of the substrate 21. Therefore, a width of the trench T near the front surface S1 is narrower than the width of the trench T near the rear surface S2.

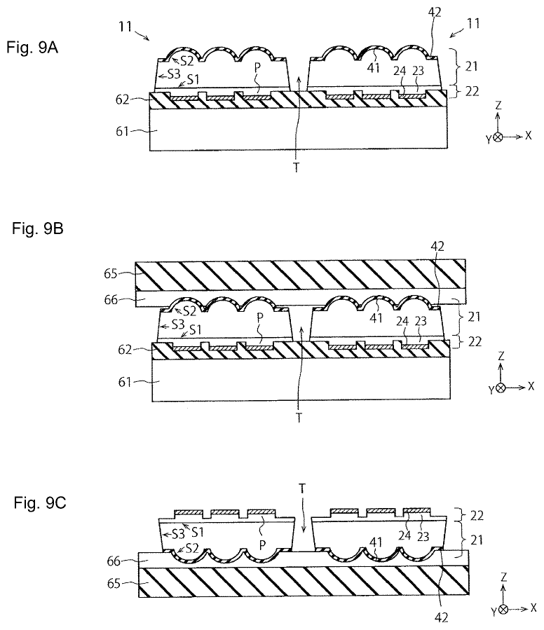

The substrate 21 is singulated into a plurality of the LD chips 11 by dry etching shown in C in FIG. 8. However, the LD chips 11 are still coupled to one another via the supporting substrate 61. The singulation from the substrate 21 into the LD chips 11 is completed via steps shown in A in FIG. 9 to C in FIG. 9.

Next, the resist film 63 is removed (A in FIG. 9). As a result, the anti-reflective film 42 is exposed to the atmosphere.

Next, a dicing tape 65 provided with an adhesive layer 66 is prepared and the dicing tape 65 is pasted to the substrate 21 via the adhesive layer 66 and the anti-reflective film 42 (B in FIG. 9). As a result, the substrate 21 is bonded to the dicing tape 65 by the adhesive layer 66. This step is referred to as tape mounting. In B in FIG. 9, the rear surface S2 of the substrate 21 faces the side of the dicing tape 65 and the front surface S1 of the substrate 21 faces an opposite side to the dicing tape 65.

Next, the substrate 21 and the dicing tape 65 are peeled off from the supporting substrate 61, orientations of the substrate 21 and the dicing tape 65 are reversed in a vertical direction, and the dicing tape 65 is pulled and stretched (C in FIG. 9). As a result, singulation of the substrate 21 into the plurality of LD chips 11 is completed. This step is referred to as debonding.

Subsequently, the LD chips 11 are peeled off from the dicing tape 65 and each LD chip 11 is mounted to the LDD substrate 12. The light-emitting apparatus 1a according to the comparative example is manufactured in this manner.

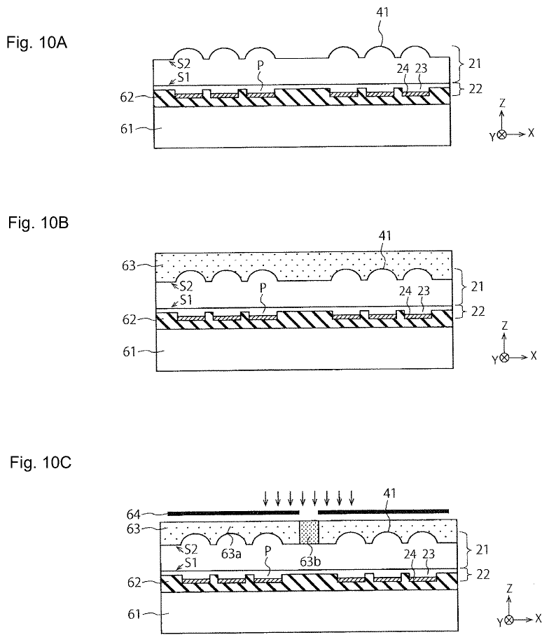

FIGS. 10 to 12 are sectional views showing a manufacturing method of the light-emitting apparatus 1a according to the first embodiment.

First, the substrate 21 for the LD chip 11 is prepared, the laminated film 22, a plurality of the light-emitting elements 23, a plurality of the anode electrodes 24, and the cathode electrode 25 (not illustrated) are formed on the front surface S1 of the substrate 21, and a plurality of the lenses 41 are formed on the rear surface S2 of the substrate 21 (Ain FIG. 10). In this step, a plurality of the post portions P including the light-emitting elements 23 are formed on the front surface S1 of the substrate 21. For example, the lenses 41 are convex lenses with a diameter of 5 μm in a plan view. Next, the substrate 21 is placed on the supporting substrate 61 via the adhesive layer 62 (A in FIG. 10). As a result, the substrate 21 is bonded to the supporting substrate 61 by the adhesive layer 62 In A in FIG. 10, the front surface S1 of the substrate 21 faces the side of the supporting substrate 61 and the rear surface S2 of the substrate 21 faces an opposite side to the supporting substrate 61.

Next, the resist film 63 is formed on the rear surface S2 of the substrate 21 (B in FIG. 10). For example, the resist film 63 is formed by applying a photoresist material to the rear surface S2 of the substrate 21 by spin coating.

Next, the resist film 63 is exposed using the photomask 64 (C in FIG. 10). As a result, a plurality of the non-exposure regions 63a and the exposure region 63b are formed inside the resist film 63. The non-exposure regions 63a are formed so as to form the chip regions 51 and the exposure region 63b is formed so as to form the scribe region 52. A width of the exposure region 63 b is, for example, 40 μm.

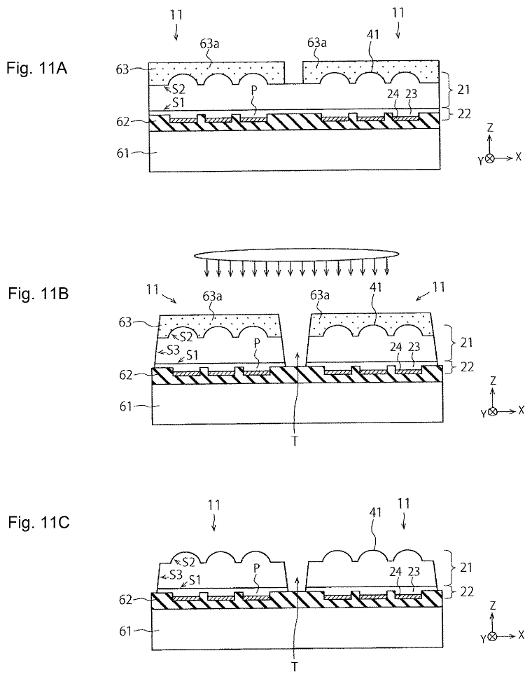

Next, the resist film 63 is developed (A in FIG. 11). As a result, the exposure region 63b is removed and the non-exposure regions 63a remain. In other words, the resist film 63 is patterned in a shape of the non-exposure regions 63a.

Next, the substrate 21 and the laminated film 22 are machined by dry etching such as RIE using the resist film 63 (B in FIG. 11). As a result, the trench T is formed so as to penetrate the substrate 21 and the laminated film 22 and a plurality of the LD chips 11 is formed from the substrate 21. Furthermore, the side surfaces S3 of the substrate 21 are formed in each LD chip 11. In B in FIG. 11, the side surfaces S3 have a tapered shape due to dry etching of the substrate 21. Therefore, a width of the trench T near the front surface S1 is narrower than the width of the trench T near the rear surface S2. In the present embodiment, the trench T with a predetermined depth is formed by machining the substrate 21 and the laminated film 22 by plasma etching. The substrate 21 according to the present embodiment is a GaAs substrate with a thickness of 100 μm.

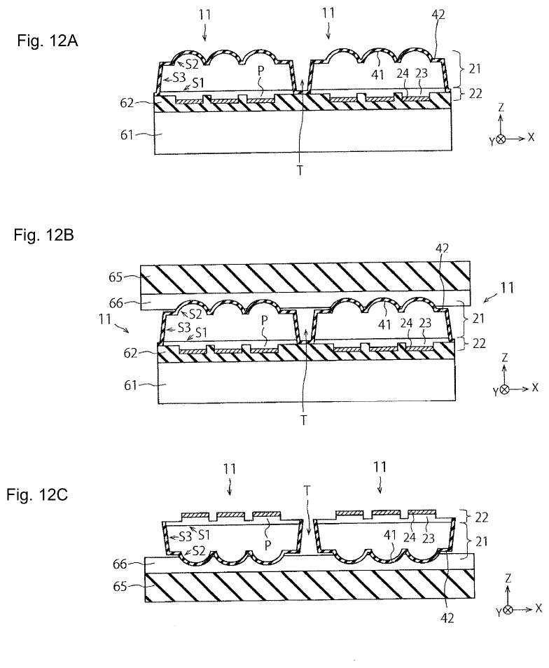

The substrate 21 is singulated into a plurality of the LD chips 11 by the dry etching shown in B in FIG. 11. However, the LD chips 11 are still coupled to one another via the supporting substrate 61. The singulation from the substrate 21 into the LD chips 11 is completed via steps shown in C in FIG. 11 to C in FIG. 12.

Next, the resist film 63 is removed (C in FIG. 11). As a result, the rear surface S2 of the substrate 21 is exposed to the atmosphere. For example, the resist film 63 is removed by chemical cleaning.

Next, the anti-reflective film 42 is formed on the rear surface S2 of the substrate 21 (A in FIG. 12). As a result, the lenses 41 are covered by the anti-reflective film 42. In A in FIG. 12, since the light-emitting elements 23 are covered by the adhesive layer 62, the anti-reflective film 42 is not in contact with the light-emitting elements 23. On the other hand, since the side surfaces S3 of the substrate 21 of each LD chip 11 is exposed, the anti-reflective film 42 according to the present embodiment is also formed on the side surfaces S3 of the substrate 21 of each LD chip 11 and also formed on side surfaces of the laminated film 22 of each LD chip 11 and on a top surface of the adhesive layer 62 in the trench T. The anti-reflective film 42 according to the present embodiment is a laminated film including a SiN film and a SiO₂ film in order and is continuously formed on the rear surface S2 and the side surfaces S3 of the substrate 21 of each LD chip 11 by sputtering.

Next, the dicing tape 65 provided with the adhesive layer 66 is prepared and the dicing tape 65 is pasted to the substrate 21 via the adhesive layer 66 and the anti-reflective film 42 (B in FIG. 12). As a result, the substrate 21 is bonded to the dicing tape 65 by the adhesive layer 66. This step is referred to as tape mounting. In B in FIG. 12, the rear surface S2 of the substrate 21 faces the side of the dicing tape 65 and the front surface S1 of the substrate 21 faces an opposite side to the dicing tape 65.

Next, the substrate 21 and the dicing tape 65 are peeled off from the supporting substrate 61, orientations of the substrate 21 and the dicing tape 65 are reversed in a vertical direction, and the dicing tape 65 is pulled and stretched (C in FIG. 12). As a result, singulation of the substrate 21 into the plurality of LD chips 11 is completed. This step is referred to as debonding. For example, the adhesive (adhesive layers 62 and 66) adhered to each LD chip 11 is removed by chemical cleaning.

Subsequently, the LD chips 11 are peeled off from the dicing tape 65 and each LD chip 11 is mounted to the LDD substrate 12. The light-emitting apparatus 1a according to the present embodiment is manufactured in this manner.

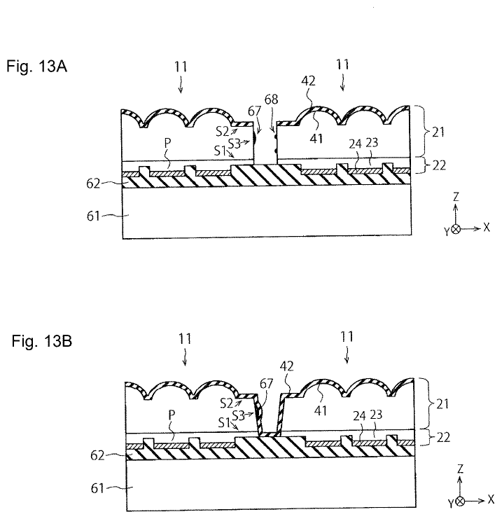

FIG. 13 is a sectional view for comparing the first embodiment and the comparative example with each other.

A in FIG. 13 shows a manufacturing method of the light-emitting apparatus 1a according to the comparative example and, specifically, shows the step shown in A in FIG. 9. When the substrate 21 is singulated, there is a risk of deposits 67 adhering to the side surfaces S3 of the substrate 21 or oxides 68 being generated on the side surfaces S3 of the substrate 21. The deposits 67 are created due to, for example, dry etching when singulating the substrate 21. On the other hand, the oxides 68 are created due to, for example, oxidation of the side surfaces of the substrate 21.

When the substrate 21 is a GaAs substrate, for example, the oxides 68 are As oxides generated by oxidation of As atoms in the GaAs substrate. There is a risk that the deposits 67 and the oxides 68 may cause dust if they fall off the side surfaces S3 of the substrate 21. While the side surfaces S3 of the substrate 21 shown in A in FIG. 13 have a non-tapered shape, alternatively, the side surfaces S3 may have a tapered shape.

B in FIG. 13 shows a manufacturing method of the light-emitting apparatus 1a according to the present embodiment and, specifically, shows the step shown in A in FIG. 12. The anti-reflective film 42 according to the present embodiment is formed so as to cover the rear surface S2 and the side surfaces S3 of the substrate 21 after the singulation of the substrate 21. Therefore, even if the deposits 67 adhere to the side surfaces S3 of the substrate 21, the adhered deposits 67 are covered by the anti-reflective film 42. Accordingly, shedding of the adhered deposits 67 can be suppressed. Furthermore, the side surfaces S3 of the substrate 21 are covered by the anti-reflective film 42 before oxidation. Accordingly, generation of the oxides 68 on the side surfaces S3 of the substrate 21 can be suppressed and, consequently, shedding of the oxides 68 can be suppressed. When the oxides 68 are generated on the side surfaces S3 of the substrate 21, shedding of the oxides 68 can be suppressed by covering the oxides 68 with the anti-reflective film 42. In this manner, according to the present embodiment, the substrate 21 after singulation can be suitably protected.

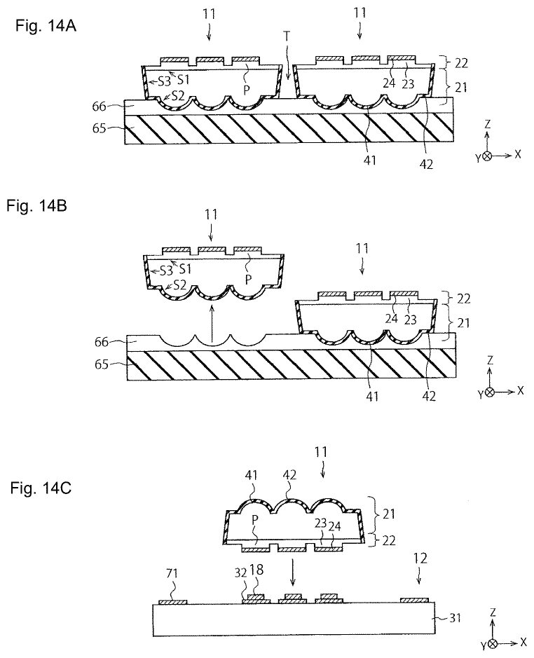

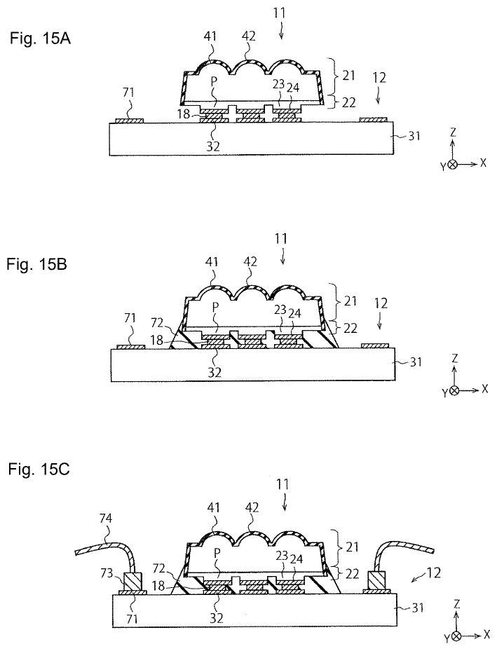

FIGS. 14 and 15 are sectional views showing a manufacturing method of the light-emitting apparatus 1a according to the first embodiment.

A in FIG. 14 shows a same step as the step shown in C in FIG. 12. First, each LD chip 11 is picked up from the dicing tape 65 (B in FIG. 14). As a result, each LD chip 11 is peeled off from the dicing tape 65. Next, an orientation of the picked-up LD chip 11 is reversed in the vertical direction and the LD chip 11 is conveyed to the LDD substrate 12 (C in FIG. 14). The LDD substrate 12 shown in C in FIG. 14 includes the substrate 31, a plurality of the connection pads 32 provided on the upper surface of the substrate 31, and a plurality of bonding pads 71 provided on the upper surface of the substrate 31. C in FIG. 14 further shows a plurality of the bumps 18 provided on the connection pads 32.

Next, the LD chip 11 is mounted on the LDD substrate 12 and each anode electrode 24 of the LD chip 11 is electrically connected by the bump 18 to the corresponding connection pad 32 of the LDD substrate 12 (A in FIG. 15). In a similar manner, the cathode electrode 25 (not illustrated) of the LD chip 11 is electrically connected by the bump 18 to the corresponding connection pad 32 of the LDD substrate 12.

Next, an underfill material 72 is embedded in a gap between the LD chip 11 and the LDD substrate 12 (B in FIG. 15). As a result, the bumps 18, the anode electrodes 24, the cathode electrode 25, the connection pads 32, and the like are to be protected by the underfill material 72. The underfill material 72 shown in B in FIG. 15 is also formed on the side surfaces S3 of the substrate 21 and the side surfaces of the laminated film 22 via the anti-reflective film 42 and is in contact with the anti-reflective film 42. For example, the underfill material 72 is an insulating film such as a resin film.

Next, a bonding wire 74 is electrically connected to each bonding pad 71 by a solder 73 (C in FIG. 15). For example, the bonding wire 74 is used to electrically connect the light-emitting apparatus 1a according to the present embodiment with other apparatuses. The light-emitting apparatus 1a according to the present embodiment is manufactured in this manner.

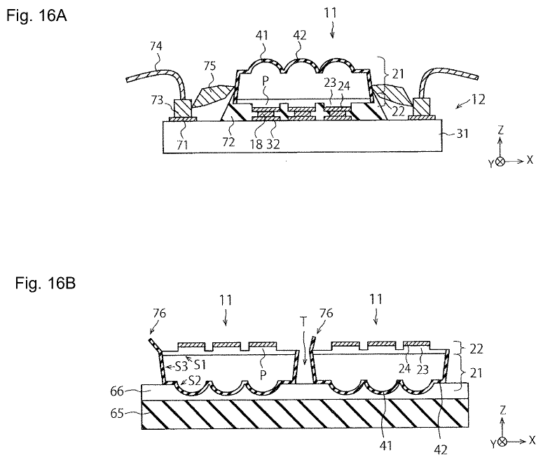

FIG. 16 is a sectional view showing details of the manufacturing method of the light-emitting apparatus 1a according to the first embodiment.

A in FIG. 16 shows a same step as the step shown in C in FIG. 15. Ain FIG. 16 shows a foreign substance 75 created on the LDD substrate 12. The foreign substance 75 is, for example, a fragment of the substrate 21 created when machining the substrate 21. When the foreign substance 75 comes into contact with a given conductor (or a given semiconductor) and another conductor (or another semiconductor), the foreign substance 75 ends up short-circuiting the conductors. For example, when the foreign substance 75 comes into contact with the substrate 21 and the solder 73, the foreign substance 75 short-circuits the substrate 21 and the solder 73. However, the rear surface S2 and the side surfaces S3 of the substrate 21 according to the present embodiment are covered by the anti-reflective film 42. Therefore, a short-circuit between the substrate 21 and a conductor (or a semiconductor) such as the solder 73 can be suppressed by the anti-reflective film 42 (refer to A in FIG. 16).

B in FIG. 16 shows a same step as the step shown in A in FIG. 14. B in FIG. 16 shows a “burr 76” that constitutes a part of the anti-reflective film 42. The burr 76 is created due to, for example, the anti-reflective film 42 formed on the upper surface of the adhesive layer 62 in the step shown in A in FIG. 12. The burr 76 can be removed from each LD chip 11 by cleaning the burr 76 with pure water in the step shown in C in FIG. 14. In this case, chemical cleansing for removing an adhesive and pure water cleaning for removing the burr 76 are performed in the step shown in C in FIG. 12.

### (4) Modification of First Embodiment

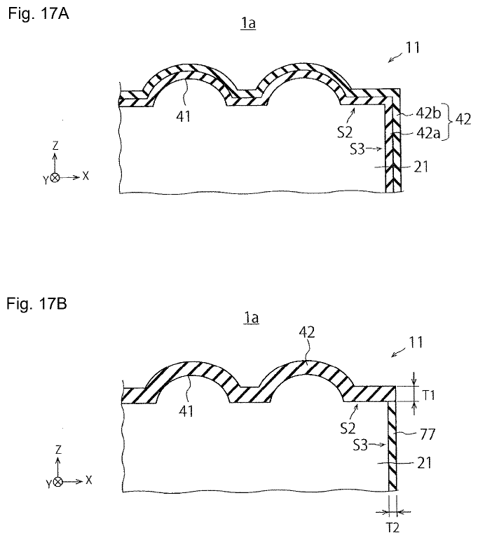

FIG. 17 is a sectional view showing a structure of the light-emitting apparatus 1a according to the first embodiment (A in FIG. 17) and a structure of the light-emitting apparatus 1a according to a modification of the first embodiment (B in FIG. 17).

As shown in A in FIG. 17, the anti-reflective film 42 according to the present embodiment includes a film 42a formed on the rear surface S2 and the side surfaces S3 of the substrate 21 and a film 42b formed via the film 42a on the rear surface S2 and the side surfaces S3 of the substrate 21. For example, the film 42a is a SiN film. For example, the film 42b is a SiO₂ film. On the other hand, for example, the substrate 21 is a GaAs substrate. In the present embodiment, the substrate 21 is a non-Si-based substrate but the anti-reflective film 42 is a Si-based film. The film 42a and the film 42b are, respectively, examples of the first film and the second film according to the present disclosure.

For example, the anti-reflective film 42 has a function of preventing light incident to the lenses 41 from inside the substrate 21 from being reflected to the inside of the substrate 21. While the anti-reflective film 42 is formed of SiN and SiO₂ in the present embodiment, alternatively, the anti-reflective film 42 may be formed of other materials.

B in FIG. 17 shows a structure of the light-emitting apparatus 1a according to the modification of the first embodiment. The light-emitting apparatus 1a according to the present modification includes the anti-reflective film 42 that covers the rear surface S2 of the substrate 21 and another film 77 that covers the side surfaces S3 of the substrate 21. The anti-reflective film 42 according to the present modification is, for example, a laminated film including a SiN film and a SiO₂ film. On the other hand, the film 77 may function as an anti-reflective film or need not function as an anti-reflective film. In addition, a film thickness T2 of the film 77 may be the same as a film thickness T1 of the anti-reflective film 42 or may differ from the film thickness T1 of the anti-reflective film 42. For example, the film 77 is an insulating film such as a SiO₂ film or a semiconductor film such as a Si film. The anti-reflective film 42 and the film 77 according to the present modification is an example of the film according to the present disclosure.

The film 77 is formed after singulation of the substrate 21. On the other hand, the anti-reflective film 42 according to the present modification may be formed before the singulation of the substrate 21 or after the singulation of the substrate 21. Furthermore, the anti-reflective film 42 according to the present modification may be formed before formation of the film 77 or after the formation of the film 77.

According to the present modification, shedding of deposits and generation of oxides can be suppressed by covering the side surfaces S3 of the substrate 21 with the film 77. In this manner, the side surfaces S3 of the substrate 21 may be protected by the anti-reflective film 42 or may be protected by another film 77. However, protecting the side surfaces S3 of the substrate 21 with the anti-reflective film 42 has an advantage in that a step of forming the film 77 can be omitted. On the other hand, protecting the side surfaces S3 of the substrate 21 with the film 77 has an advantage in that a material of the film 77 can be freely selected.

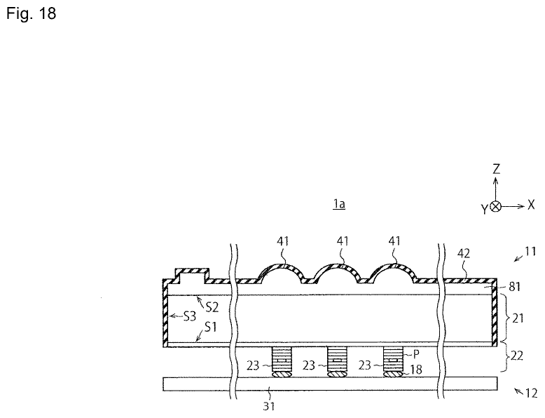

FIG. 18 is a sectional view showing a structure of the light-emitting apparatus 1a according to another modification of the first embodiment.

The light-emitting apparatus 1a according to the present modification includes a semiconductor layer 81 in addition to the constituent elements of the light-emitting apparatus 1a according to the present embodiment. The semiconductor layer 81 is formed on the rear surface S2 of the substrate 21. While the light-emitting elements 23 and the lenses 41 according to the present modification are respectively formed on the front surface S1 and the rear surface S2 of the substrate 21, the lenses 41 according to the present modification are formed as a part of the semiconductor layer 81 instead of a part of the substrate 21. In addition, the anti-reflective film 42 according to the present modification is formed on an upper surface of the semiconductor layer 81, side surfaces of the semiconductor layer 81, side surfaces S3 of the substrate 21, and side surfaces of the laminated film 22 and covers the lenses 41. For example, the semiconductor layer 81 is a Si layer.

As described above, the light-emitting apparatus 1a according to the present embodiment includes the anti-reflective film 42 provided on the side surfaces S3 of the substrate 21. Therefore, according to the present embodiment, the substrate 21 after singulation can be suitably protected by the anti-reflective film 42. For example, shedding of deposits from the side surfaces S3 of the substrate 21 and generation of oxides on the side surfaces S3 of the substrate 21 can be suppressed by covering the side surfaces S3 of the substrate 21 with the anti-reflective film 42.

### Second Embodiment

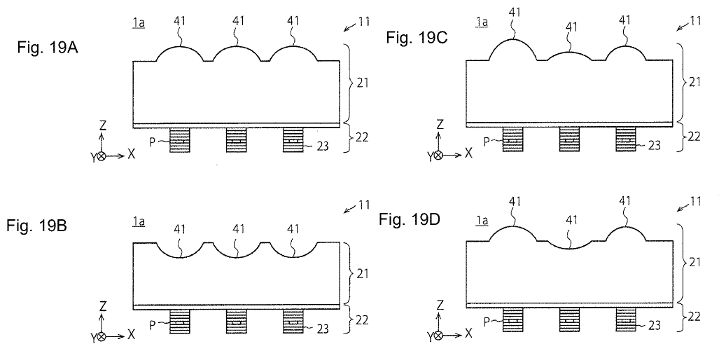

FIG. 19 is a sectional view showing an example of a structure of the substrate 21 of the light-emitting apparatus 1a according to a second embodiment. While each of A in FIG. 19 to D in FIG. 19 shows a cross section of the substrate 21 of the light-emitting apparatus 1a and the like in a similar manner to A in FIG. 5, illustration of the anti-reflective film 42 and the like has been omitted.

The substrate 21 in A in FIG. 19 includes a plurality of lenses 41 that are convex lenses corresponding one-to-one with the light-emitting elements 23 in a similar manner to the substrate 21 in A in FIG. 5. In a similar manner, the substrate 21 in each of B in FIG. 19 to D in FIG. 19 includes a plurality of lenses 41 that correspond one-to-one with the light-emitting elements 23. However, the substrate 21 in B in FIG. 19 includes concave lens, the substrate 21 in C in FIG. 19 includes convex lenses having mutually different shapes (curvatures), and the substrate 21 in D in FIG. 19 includes both convex lenses and concave lenses. In this manner, each of the lenses 41 according to the present embodiment may be a convex lens or a concave lens. In addition, each of the lenses 41 according to the present embodiment, as a third embodiment as described later, may be a lens having a convex shape in a mode other than a convex lens or a lens having a concave shape in a mode other than a concave lens.

### Third Embodiment

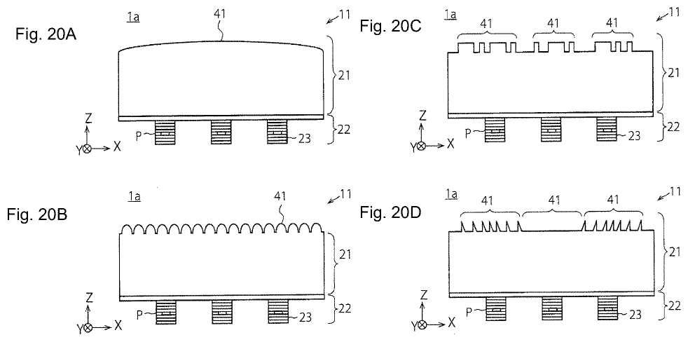

FIG. 20 is a sectional view showing an example of a structure of the substrate 21 of the light-emitting apparatus 1a according to a third embodiment. While each of A in FIG. 20 to D in FIG. 20 shows a cross section of the substrate 21 of the light-emitting apparatus 1a and the like in a similar manner to A in FIG. 5, illustration of the anti-reflective film 42 and the like has been omitted.

In the substrate 21 in A in FIG. 20, the light-emitting elements 23 and the lenses 41 correspond N-to-1 (where N is an integer equal to or greater than 2) with each other. Therefore, in A in FIG. 20, light emitted from N-number of light-emitting elements 23 is incident to one lens 41. On the other hand, in the substrate 21 in B in FIG. 20, the light-emitting elements 23 and the lenses 41 correspond 1-to-N with each other. Therefore, in B in FIG. 20, light emitted from one light-emitting element 23 is incident to N-number of lenses 41. In this manner, each of the lenses 41 according to the present embodiment need not correspond 1-to-1 with each of the light-emitting elements 23.

In the substrate 21 in C in FIG. 20, the light-emitting elements 23 and the lenses 41 correspond 1-to-1 with each other. However, the substrate 21 in C in FIG. 20 includes a Fresnel lens with a convex shape. In addition, in the substrate 21 in D in FIG. 20, the light-emitting elements 23 and the lenses 41 correspond 1-to-1 with each other. However, the substrate 21 in D in FIG. 20 includes a binary lens with a convex shape and a flat lens. In this manner, each of the lenses 41 according to the present embodiment may be a lens other than a convex lens or a concave lens.

While the light-emitting apparatus 1a according to the first to third embodiments is used as a light source of the ranging apparatus 1, alternatively, the light-emitting apparatus 1a may be used in other modes. For example, the light-emitting apparatus 1a according to the embodiments may be used as a light source of an optical device such as a printer or as a lighting apparatus.

While embodiments of the present disclosure have been described above, various modifications of the embodiments may be made and implemented without deviating from the gist of the present disclosure. For example, two or more embodiments may be combined and implemented.

The present disclosure can also be configured as follows.

(1)

A light-emitting apparatus, including:
a substrate;
a light-emitting element provided on a first surface of the substrate;
a lens provided on a second surface of the substrate; and
a film provided on a third surface between the first surface and the second surface of the substrate.
   (2)

The light-emitting apparatus according to (1), wherein the film is provided on the second surface and the third surface of the substrate.

(3)

The light-emitting apparatus according to (2), wherein the film covers the lens.

(4)

The light-emitting apparatus according to (1), wherein the film is not in contact with the light-emitting element.

(5)

The light-emitting apparatus according to (1), wherein the film is an anti-reflective film.

(6)

The light-emitting apparatus according to (1), wherein the film contains silicon.

(7)

The light-emitting apparatus according to (1), wherein the film includes a first film provided on the third surface of the substrate and a second film provided via the first film on the third surface of the substrate.

(8)

The light-emitting apparatus according to (7), wherein the first film contains silicon and nitrogen and the second film contains silicon and oxygen.

(9)

The light-emitting apparatus according to (1), wherein the substrate is a compound semiconductor substrate.

(10)

The light-emitting apparatus according to (9), wherein the substrate contains gallium and arsenic.

(11)

The light-emitting apparatus according to (1), wherein the third surface of the substrate has a tapered shape.

(12)

A manufacturing method of a light-emitting apparatus includes the steps of:
forming a light-emitting element on a first surface of a substrate;
forming a lens on a second surface of the substrate;
singulating the substrate; and
forming a film on a third surface between the first surface and the second surface of the substrate after singulation of the substrate.
   (13)

The manufacturing method of a light-emitting apparatus according to (12), wherein the film is formed on the second surface and the third surface of the substrate after singulation of the substrate.

(14)

The manufacturing method of a light-emitting apparatus according to (13), wherein the film is formed so as to cover the lens.

(15)

The manufacturing method of a light-emitting apparatus according to (12), wherein the film is formed so as not to come into contact with the light-emitting element.

(16)

The manufacturing method of a light-emitting apparatus according to (12), wherein the film is an anti-reflective film.

(17)

The manufacturing method of a light-emitting apparatus according to (12), wherein the film is formed so as to include a first film formed on the third surface of the substrate and a second film formed via the first film on the third surface of the substrate.

(18)

The manufacturing method of a light-emitting apparatus according to (12), wherein the substrate is a compound semiconductor substrate.

(19)

The manufacturing method of a light-emitting apparatus according to (12), wherein the third surface of the substrate is formed by singulation of the substrate.

(20)

The manufacturing method of a light-emitting apparatus according to (12), wherein the singulation of the substrate is performed by dry etching.

### REFERENCE SIGNS LIST

1 Ranging apparatus
1a Light-emitting apparatus
2 Light-emitting unit
2a Light-emitting element
3 Driving unit
4 Power supply circuit
5 Light-emitting side optical system
6 Light-receiving side optical system
7 Light-receiving unit
8 Signal processing unit
9 Control unit
9a Ranging unit
10 Temperature detecting unit
11 LD chip
12 LDD substrate
13 Mounting substrate
14 Heat dissipation substrate
15 Correcting lens holding unit
16 Correcting lens
17 Wiring
18 Bump
21 Substrate
22 Laminated film
23 Light-emitting element
24 Anode electrode
25 Cathode electrode
31 Substrate
32 Connection pad
41 Lens
42 Anti-reflective film
42a Film
42b Film
51 Chip region
51a Lens region
51b Peripheral region
52 Scribe region
52a Scribe line
52b Scribe line
61 Supporting substrate
62 Adhesive layer
63 Resist film
63a Non-exposure region
63b Exposure region
64 Photomask
65 Dicing tape
66 Adhesive layer
67 Deposit
68 Oxide
71 Bonding pad
72 Underfill material
73 Solder
74 Bonding wire
75 Foreign substance
76 Burr
77 Film
81 Semiconductor layer

1. A light-emitting apparatus, comprising:
a substrate;
a light-emitting element provided on a first surface of the substrate;
a lens provided on a second surface of the substrate; and
a film provided on a third surface between the first surface and the second surface of the substrate.

2. The light-emitting apparatus according to claim 1, wherein the film is provided on the second surface and the third surface of the substrate.

3. The light-emitting apparatus according to claim 2, wherein the film covers the lens.

4. The light-emitting apparatus according to claim 1, wherein the film is not in contact with the light-emitting element.

5. The light-emitting apparatus according to claim 1, wherein the film is an anti-reflective film.

6. The light-emitting apparatus according to claim 1, wherein the film contains silicon.

7. The light-emitting apparatus according to claim 1, wherein the film includes a first film provided on the third surface of the substrate and a second film provided via the first film on the third surface of the substrate.

8. The light-emitting apparatus according to claim 7, wherein the first film contains silicon and nitrogen and the second film contains silicon and oxygen.

9. The light-emitting apparatus according to claim 1, wherein the substrate is a compound semiconductor substrate.

10. The light-emitting apparatus according to claim 9, wherein the substrate contains gallium and arsenic.

11. The light-emitting apparatus according to claim 1, wherein the third surface of the substrate has a tapered shape.

12. A manufacturing method of a light-emitting apparatus, comprising the steps of:
forming a light-emitting element on a first surface of a substrate;
forming a lens on a second surface of the substrate;
singulating the substrate; and
forming a film on a third surface between the first surface and the second surface of the substrate after singulation of the substrate.

13. The manufacturing method of a light-emitting apparatus according to claim 12, wherein the film is formed on the second surface and the third surface of the substrate after singulation of the substrate.

14. The manufacturing method of a light-emitting apparatus according to claim 13, wherein the film is formed so as to cover the lens.

15. The manufacturing method of a light-emitting apparatus according to claim 12, wherein the film is formed so as not to come into contact with the light-emitting element.

16. The manufacturing method of a light-emitting apparatus according to claim 12, wherein the film is an anti-reflective film.

17. The manufacturing method of a light-emitting apparatus according to claim 12, wherein the film is formed so as to include a first film formed on the third surface of the substrate and a second film formed via the first film on the third surface of the substrate.

18. The manufacturing method of a light-emitting apparatus according to claim 12, wherein the substrate is a compound semiconductor substrate.

19. The manufacturing method of a light-emitting apparatus according to claim 12, wherein the third surface of the substrate is formed by singulation of the substrate.

20. The manufacturing method of a light-emitting apparatus according to claim 12, wherein the singulation of the substrate is performed by dry etching.
